(19) United States
(12) Patent Application Publication
(10) Pub. No.: US 2025/0142768 A1
(43) Pub. Date: May 1, 2025

(54) ROTATABLE FAN OUTLET FOR DIFFERENT USER SCENARIOS

(71) Applicant: DELL PRODUCTS L.P., Round Rock, TX (US)

(72) Inventors: Jer-Yo Lee, Taipei City (TW); Yu-Min Huang, Yilan County (TW); Chi-Yung Chiang, Taichung City (TW); Mei-Ling Pan, Taipei City (TW); Ya Chen Chang, Taipei City (TW); Jung Jung Wang, Ershui Township (TW); Huan-Chun Wu, Taipei City (TW); Po-Fei Tsai, New Taipei City (TW); Hao Wu Yang, Taipei City (TW)

(21) Appl. No.: 18/500,101

(22) Filed: Nov. 1, 2023

(51) Int. Cl. H05K 7/20

(52) U.S. Cl. CPC H05K 7/20209; H05K 7/20145

(57) ABSTRACT

An information handling system includes an air mover and a management controller configured to determine an airflow direction of the air mover. The air mover includes an enclosure base and a gear disposed within the enclosure base. The gear is configured to rotate an outlet frame, and the outlet frame is configured to rotate within the enclosure base. The outlet frame includes a nozzle structure that is configured to guide the airflow direction according to a determination of the management controller.

### FIELD OF THE DISCLOSURE

The present disclosure generally relates to information handling systems, and more particularly relates to a rotatable fan outlet for different user scenarios.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes an air mover and a management controller configured to determine an airflow direction of the air mover. The air mover includes an enclosure base and a gear disposed within the enclosure base. The gear is configured to rotate an outlet frame, and the outlet frame is configured to rotate within the enclosure base. The outlet frame includes a nozzle structure that is configured to guide the airflow direction according to a determination of the management controller.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram illustrating an information handling system, according to an embodiment of the present disclosure;

FIG. 2 is a diagram of an air mover with a rotatable outlet for different user scenarios, according to an embodiment of the present disclosure;

FIG. 3 is a perspective view of an air mover with a rotatable outlet for different user scenarios, according to an embodiment of the present disclosure;

FIG. 4 is a perspective view of an enclosure base of an air mover with a rotatable outlet for different user scenarios, according to an embodiment of the present disclosure;

FIG. 5 is a diagram of an information handling system with an air mover, according to an embodiment of the present disclosure;

FIG. 6 is an exploded perspective view of an air mover with a rotatable air mover outlet for different user scenarios, according to an embodiment of the present disclosure;

FIG. 7 is a diagram of an air mover depicting directions of the airflow based on the orientation of an outlet frame, according to an embodiment of the present disclosure;

FIG. 8 is a perspective view of air mover, according to an embodiment of the present disclosure;

FIG. 9 is a perspective view of an enclosure base, according to an embodiment of the present disclosure;

FIG. 10 is a diagram of an information handling system with an air mover, according to an embodiment of the present disclosure;

FIG. 11 is a diagram of an air mover with a rotatable air mover outlet for different user scenarios, according to an embodiment of the present disclosure;

FIG. 12 is a perspective view of an air mover, according to an embodiment of the present disclosure;

FIG. 13 is a perspective view of an enclosure base, according to an embodiment of the present disclosure;

FIG. 14 is a diagram of an air mover with a rotatable air mover outlet for different user scenarios, according to an embodiment of the present disclosure;

FIG. 15 is a perspective view of an air mover, according to an embodiment of the present disclosure;

FIG. 16 is a perspective view of an enclosure base, according to an embodiment of the present disclosure;

FIG. 17 is a diagram of an information handling system with an air mover that is configured with a rotatable fan outlet for different user scenarios, according to an embodiment of the present disclosure; and

FIG. 18 is a flowchart of a method for monitoring and/or controlling an air mover that is configured with a rotatable fan outlet for different user scenarios, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

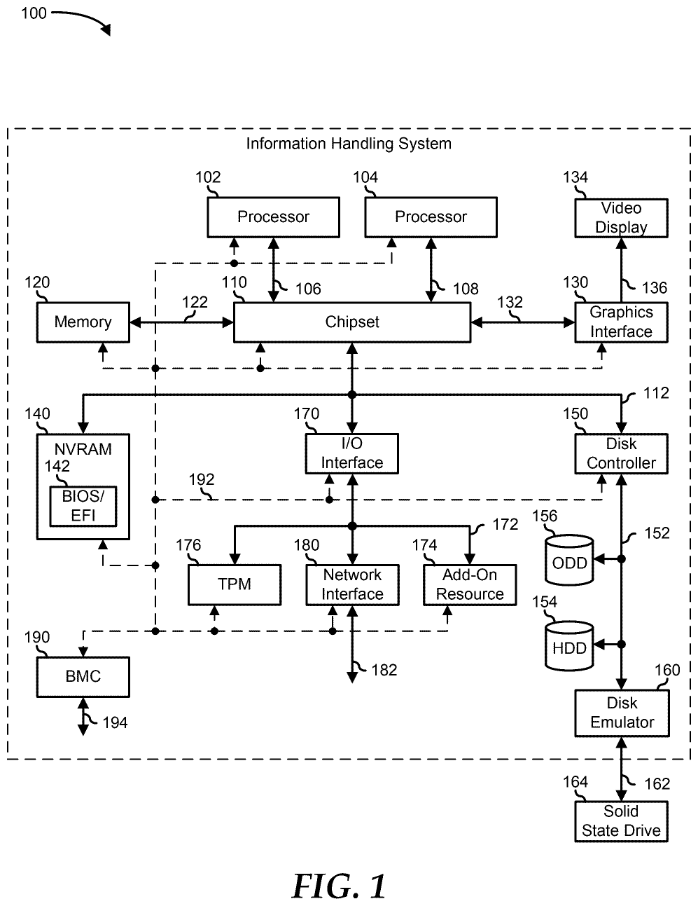

FIG. 1 illustrates an embodiment of an information handling system 100 including processors 102 and 104, a chipset 110, a memory 120, a graphics adapter 130 connected to a video display 134, a non-volatile RAM (NV-RAM) 140 that includes a basic input and output system/extensible firmware interface (BIOS/EFI) module 142, a disk controller 150, a hard disk drive (HDD) 154, an optical disk drive 156, a disk emulator 160 connected to a solid-state drive (SSD) 164, an input/output (I/O) interface 170 connected to an add-on resource 174 and a trusted platform module (TPM) 176, a network interface 180, and a baseboard management controller (BMC) 190. Processor 102 is connected to chipset 110 via processor interface 106, and processor 104 is connected to the chipset via processor interface 108. In a particular embodiment, processors 102 and 104 are connected together via a high-capacity coherent fabric, such as a HyperTransport link, a QuickPath Interconnect, or the like. Chipset 110 represents an integrated circuit or group of integrated circuits that manage the data flow between processors 102 and 104 and the other elements of information handling system 100. In a particular embodiment, chipset 110 represents a pair of integrated circuits, such as a northbridge component and a southbridge component. In another embodiment, some or all of the functions and features of chipset 110 are integrated with one or more of processors 102 and 104.

Memory 120 is connected to chipset 110 via a memory interface 122. An example of memory interface 122 includes a Double Data Rate (DDR) memory channel and memory 120 represents one or more DDR Dual In-Line Memory Modules (DIMMs). In a particular embodiment, memory interface 122 represents two or more DDR channels. In another embodiment, one or more of processors 102 and 104 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 120 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 130 is connected to chipset 110 via a graphics interface 132 and provides a video display output 136 to a video display 134. An example of a graphics interface 132 includes a Peripheral Component Interconnect-Express (PCIe) interface and graphics adapter 130 can include a four-lane (×4) PCIe adapter, an eight-lane (×8) PCIe adapter, a 16-lane (×16) PCIe adapter, or another configuration, as needed or desired. In a particular embodiment, graphics adapter 130 is provided down on a system printed circuit board (PCB). Video display output 136 can include a Digital Video Interface (DVI), a High-Definition Multimedia Interface (HDMI), a DisplayPort interface, or the like, and video display 134 can include a monitor, a smart television, an embedded display such as a laptop computer display, or the like.

NV-RAM 140, disk controller 150, and I/O interface 170 are connected to chipset 110 via an I/O channel 112. An example of I/O channel 112 includes one or more point-to-point PCIe links between chipset 110 and each of NV-RAM 140, disk controller 150, and I/O interface 170. Chipset 110 can also include one or more other I/O interfaces, including a PCIe interface, an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. NV-RAM 140 includes BIOS/EFI module 142 that stores machine-executable code (BIOS/EFI code) that operates to detect the resources of information handling system 100, to provide drivers for the resources, to initialize the resources, and to provide common access mechanisms for the resources. The functions and features of BIOS/EFI module 142 will be further described below.

Disk controller 150 includes a disk interface 152 that connects the disc controller to a hard disk drive (HDD) 154, to an optical disk drive (ODD) 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an institute of electrical and electronics engineers (IEEE) 1394 (Firewire) interface, a proprietary interface, or a combination thereof. Alternatively, SSD 164 can be disposed within information handling system 100.

I/O interface 170 includes a peripheral interface 172 that connects the I/O interface to add-on resource 174, to TPM 176, and to network interface 180. Peripheral interface 172 can be the same type of interface as I/O channel 112 or can be a different type of interface. As such, I/O interface 170 extends the capacity of I/O channel 112 when peripheral interface 172 and the I/O channel are of the same type, and the I/O interface translates information from a format suitable to the I/O channel to a format suitable to the peripheral interface 172 when they are of a different type. Add-on resource 174 can include a data storage system, an additional graphics interface, a network interface card (NIC), a sound/video processing card, another add-on resource, or a combination thereof. Add-on resource 174 can be on a main circuit board, on separate circuit board, or add-in card disposed within information handling system 100, a device that is external to the information handling system, or a combination thereof.

Network interface 180 represents a network communication device disposed within information handling system 100, on a main circuit board of the information handling system, integrated onto another component such as chipset 110, in another suitable location, or a combination thereof. Network interface 180 includes a network channel 182 that provides an interface to devices that are external to information handling system 100. In a particular embodiment, network channel 182 is of a different type than peripheral interface 172, and network interface 180 translates information from a format suitable to the peripheral channel to a format suitable to external devices.

In a particular embodiment, network interface 180 includes a NIC or host bus adapter (HBA), and an example of network channel 182 includes an InfiniBand channel, a Fibre Channel, a Gigabit Ethernet channel, a proprietary channel architecture, or a combination thereof. In another embodiment, network interface 180 includes a wireless communication interface, and network channel 182 includes a Wi-Fi channel, a near-field communication (NFC)® or Bluetooth-Low-Energy (BLE) channel, a cellular based interface such channel, a Bluetooth® as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 182 can be connected to an external network resource (not illustrated). The network resource can include another information handling system, a data storage system, another network, a grid management system, another suitable resource, or a combination thereof.

BMC 190 is connected to multiple elements of information handling system 100 via one or more management interface 192 to provide out of band monitoring, maintenance, and control of the elements of the information handling system. As such, BMC 190 represents a processing device different from processor 102 and processor 104, which provides various management functions for information handling system 100. For example, BMC 190 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 190 can vary considerably based on the type of information handling system. BMC 190 can operate in accordance with an Intelligent Platform Management Interface (IPMI). Examples of BMC 190 include an Integrated Dell® Remote Access Controller (iDRAC).

Management interface 192 represents one or more out-of-band communication interfaces between BMC 190 and the elements of information handling system 100, and can include a I²C bus, a System Management Bus (SMBus), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 100, that is apart from the execution of code by processors 102 and 104 and procedures that are implemented on the information handling system in response to the executed code.

BMC 190 operates to monitor and maintain system firmware, such as code stored in BIOS/EFI module 142, option ROMs for graphics adapter 130, disk controller 150, add-on resource 174, network interface 180, or other elements of information handling system 100, as needed or desired. In particular, BMC 190 includes a network interface 194 that can be connected to a remote management system to receive firmware updates, as needed or desired. Here, BMC 190 receives the firmware updates, stores the updates to a data storage device associated with the BMC, transfers the firmware updates to NV-RAM of the device or system that is the subject of the firmware update, thereby replacing the currently operating firmware associated with the device or system, and reboots information handling system, whereupon the device or system utilizes the updated firmware image.

BMC 190 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 190, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 190 is included on a main circuit board (such as a baseboard, a motherboard, or any combination thereof) of information handling system 100 or is integrated onto another element of the information handling system such as chipset 110, or another suitable element, as needed or desired. As such, BMC 190 can be part of an integrated circuit or a chipset within information handling system 100. An example of BMC 190 includes an iDRAC, or the like. BMC 190 may operate on a separate power plane from other resources in information handling system 100. Thus BMC 190 can communicate with the management system via network interface 194 while the resources of information handling system 100 are powered off. Here, information can be sent from the management system to BMC 190 and the information can be stored in a RAM or NV-RAM associated with the BMC. Information stored in the RAM may be lost after power-down of the power plane for BMC 190, while information stored in the NV-RAM may be saved through a power-down/power-up cycle of the power plane for the BMC.

Information handling system 100 can include additional components and additional busses, not shown for clarity. For example, information handling system 100 can include multiple processor cores, audio devices, and the like. While a particular arrangement of bus technologies and interconnections is illustrated for the purpose of example, one of skill will appreciate that the techniques disclosed herein are applicable to other system architectures. Information handling system 100 can include multiple central processing units (CPUs) and redundant bus controllers. One or more components can be integrated together. Information handling system 100 can include additional buses and bus protocols, for example, I²C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 100 can include processing resources for executing machine-executable code, such as processor 102, a programmable logic array (PLA), an embedded device such as a System-on-a-Chip (SoC), or other control logic hardware. Information handling system 100 can also include one or more computer-readable media for storing machine-executable code, such as software or data.

Hot spots on surfaces of portable information handling systems can vary across different user scenarios. This is due to the operation of various components situated in different locations. Currently, thermal design typically aims to primarily prioritize providing fixed solutions tailored to specific situations. For example in some portable information handling systems, an additional fan is incorporated to cool a memory under high-stress conditions, such as overclocking. However, this additional fan typically remains inactive during other scenarios. Accordingly, the present disclosure provides an air mover assembly with a rotatable outlet, wherein the air mover can cool one area under a first operating condition and a second area under a second operating condition.

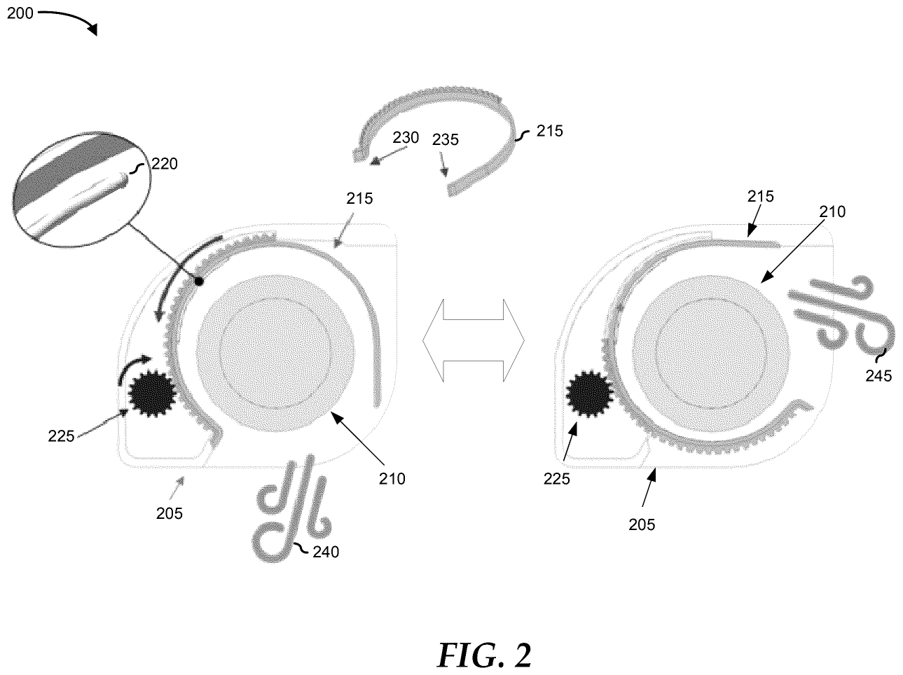

FIG. 2 shows an air mover 200 with a rotatable outlet for different user scenarios. Air mover 200 includes an enclosure base 205, a set of blades 210, an outlet frame 215, a rib 220, and a gear 225. Set of blades 210, outlet frame 215, rib 220, and gear 225 disposed within enclosure base 205 and a top cover. Outlet frame 215 may be configured as a geared circular structure with the nozzle shape structure provided by a first end 230 and a second end 235. The nozzle-shaped structure may be used to guide airflow in a particular direction.

Air mover 200 may be associated with a motor for driving set of blades 210 or an impeller for moving air, wherein set of blades 210 may be physically coupled to enclosure base 205. The motor may also be used in changing the direction of the airflow by rotating gear 225 which in turn may rotate outlet frame 215. The motor coupled to gear 225 may be a step motor to provide more control of the airflow direction.

Outlet frame 215 includes a circular outer gear that may be configured to engage with gear 225 and may be mounted on enclosure base 205. Together, the circular outer gear of outlet frame 215 and gear 225 may cause outlet frame 215 to rotate, which may cause first end 230 and second end 235 to be at different locations along enclosure base 205. As air may flow between first end 230 and second end 235, this may cause a change in the direction of the airflow, such as from an airflow direction 240 to airflow direction 245 or vice versa.

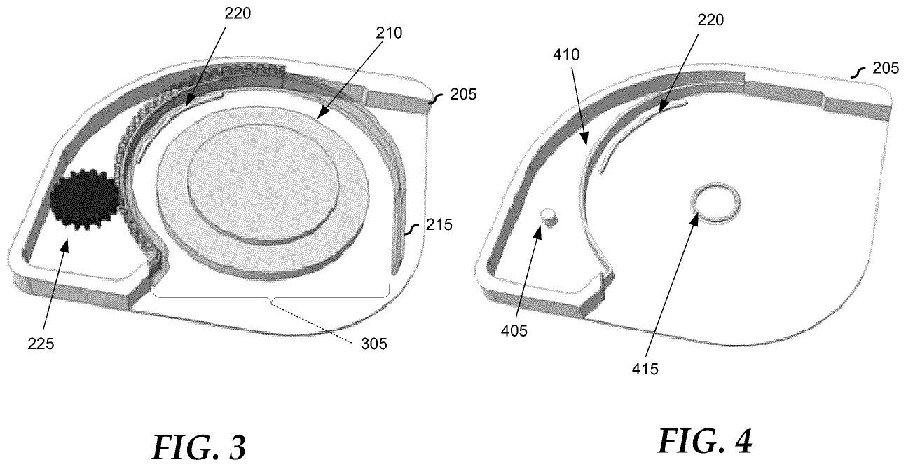

FIG. 3 shows a perspective view of air mover 200. Air mover 200 includes enclosure base 205, set of blades 210, outlet frame 215, rib 220, and gear 225. The rotation of outlet frame 215 may be held in place by rib 220. The airflow may flow through airflow opening 305 which is shaped by the ends of outlet frame 215. In the examples above, air mover 200 may include a top cover that may be physically coupled with enclosure base 205. However, for ease in showing the components, air mover 200 is presented with the top cover removed.

FIG. 4 shows a perspective view of enclosure base 205. Enclosure base 205 includes rib 220, a peg 405, an outlet frame guide 410, and a ribbed enclosure opening 415. Outlet frame 215 may be configured to rotate along outlet frame guide 410 and may be kept in place by rib 220. While ribbed enclosure opening 415 may keep set of blades 210 in its place.

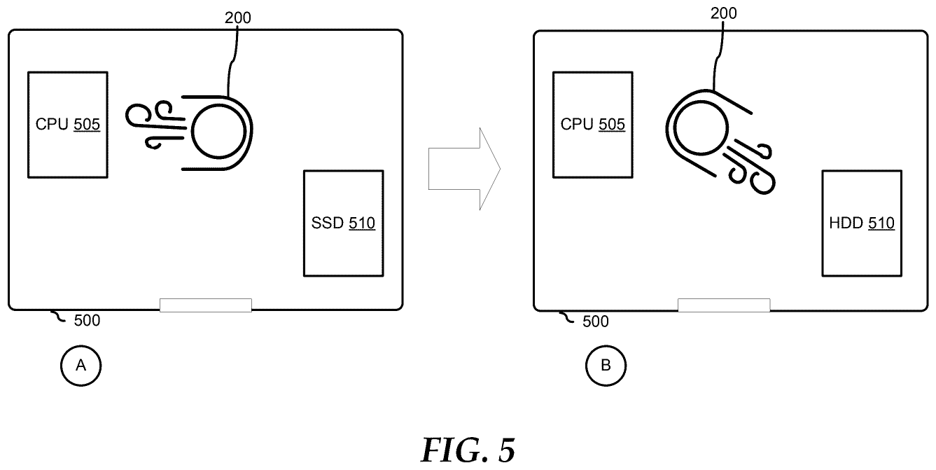

FIG. 5 shows an information handling system 500 with air mover 200. Information handling system 500, which is similar to information handling system 100 of FIG. 1, also includes a CPU 505 and an SSD 510. CPU 505 may be similar to processor 102 of FIG. 1 while SSD 510 may be similar to SSD 164 of FIG. 1. In this example, SSD 310 is disposed within information handling system 500.

FIG. 5 is annotated with a series of letters A and B. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations.

At stage A, the temperature of CPU 505 may have exceeded a temperature threshold and/or may be higher than the temperature of SSD 510. Accordingly, the orientation of air mover 200 may be configured such that the airflow is directed toward CPU 505. For example, the outlet frame of air mover 200 may be rotated such that the airflow is directed to CPU 505. This may lower the temperature of CPU 505. In addition, the skin temperature of the information handling system above CPU 505 may also be reduced.

At stage B, the temperature of SSD 510 may have exceeded a temperature threshold and/or may be higher than the temperature of CPU 505. Accordingly, the orientation of air mover 200 may be configured such that the airflow is directed towards SSD 510. For example, the outlet frame of air mover 200 may be rotated such that the airflow is directed towards SSD 510. This may lower the temperature of SSD 510. In addition, the skin temperature of the information handling system above SSD 510 may also be reduced.

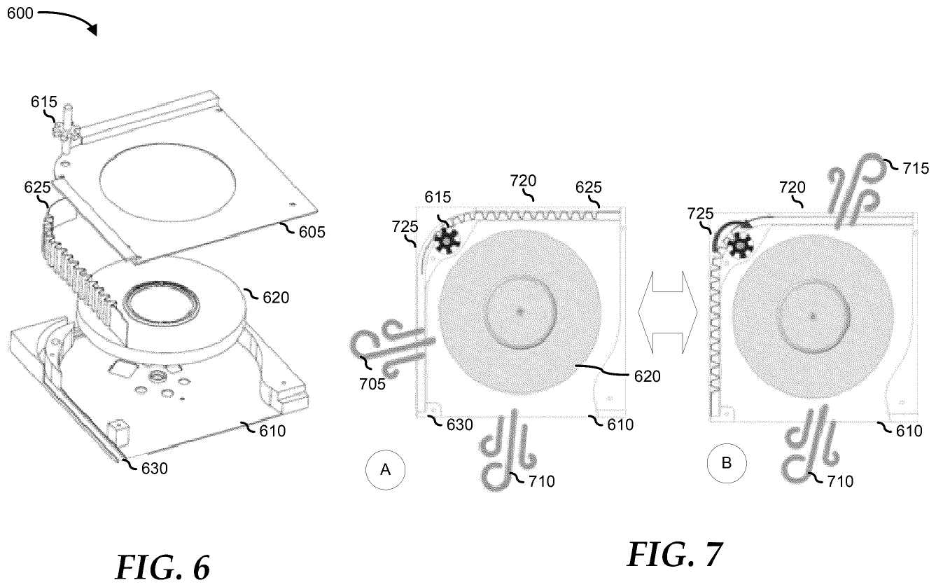

FIG. 6 shows an exploded view of air mover 600 with a rotatable air mover outlet for different user scenarios. Air mover 600 includes an enclosure top cover 605, a set of blades 620, an enclosure base 610, a gear 615, and an outlet frame 625. Set of blades 620, gear, and outlet frame 625 may be disposed within enclosure base 610 and enclosure top cover 605. Gear 615 may be mounted on enclosure base 610 and pass through enclosure top cover 605. Enclosure base 610 includes a frame rail 630 along an inner section of its sides. Set of blades 620 and outlet frame 625 may be disposed between enclosure top cover 605 and enclosure base 610, which makes up an enclosure for air mover 600. In this example, air mover 600 includes two outlets for the airflow, wherein the airflow may be directed in two different directions at the same time.

In one embodiment, outlet frame 625 may have a jagged section that may be configured to engage with gear 615. The jagged section may be between a first non-jagged section and a second non-jagged section. Together, the jagged section of outlet frame 625 and gear 615 may cause outlet frame 625 to move or slide along frame rail 630. In addition, frame rail 630 may also prevent outlet frame 625 from sliding out. A step motor may be utilized to rotate gear 615, enabling control over the directions of the airflow. Outlet frame 625 may be manufactured using both metal and polymer materials. For example, the jagged section of outlet frame 625 may be made of a polymer material while the non-jagged section of outlet frame 625 may be made of metal.

FIG. 7 shows air mover 600 depicting directions of the airflow based on the orientation of outlet frame 625. FIG. 7 is annotated with a series of letters A and B. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations.

At stage A, air mover 600 is oriented such that air flows in an airflow direction 705 and an airflow direction 710. At this orientation, the jagged section of outlet frame 625 may be proximate to a side 720 of air mover 600. From stage A, air mover 600 may transition into stage B by rotation of gear 615 which moves outlet frame 625 from being proximate with side 720 to proximate with side 725.

At stage B, air mover 600 is oriented such that air flows in airflow direction 710 and an airflow direction 715. At this orientation, outlet frame 625 is proximate to a side 725 of air mover 600. From stage B, air mover 600 may transition into stage A by rotation of gear 615 moving outlet frame 625 from being proximate with side 725 to proximate with side 720.

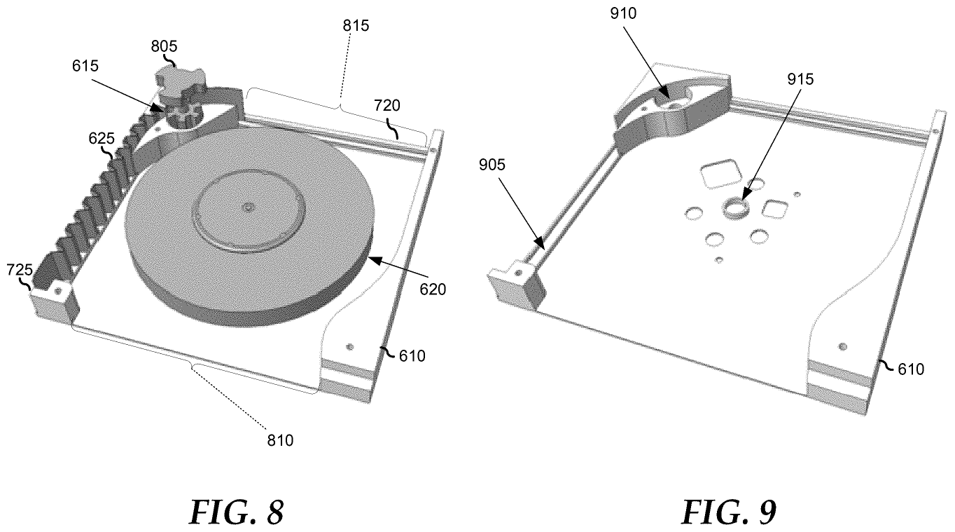

FIG. 8 shows a perspective view of air mover 600. Air mover 600 includes set of blades 620, enclosure base 610, gear 615, outlet frame 625, and a gear cap 805. In this example, air may flow through an airflow opening 810. In addition, air may also flow through an airflow opening 815 as the jagged section of outlet frame 625 is currently at side 725 of enclosure base 610 blocking air to flow at that side. If gear 615 rotates and outlet frame 625 slides to side 720 of enclosure base 610, the jagged section of outlet frame 625 may block airflow opening 815 at side 720 but unblock side 725. This may allow air to flow through an airflow opening at side 725. Although gear 615 is typically rotated using a motor, gear cap 805 may be used to rotate gear 615 manually.

FIG. 9 shows a perspective view of enclosure base 610. Enclosure base 610 includes a guide 905, a gear mount 910, and a ribbed enclosure opening 915. Guide 905 may be used to keep outlet frame 625 from sliding out of position, while gear 615 may be mounted on a gear mount 910. Ribbed enclosure opening 915 may keep set of blades 620 in its place. In some of the examples above, air mover 600 is presented with enclosure top cover 605 removed for ease in showing the components.

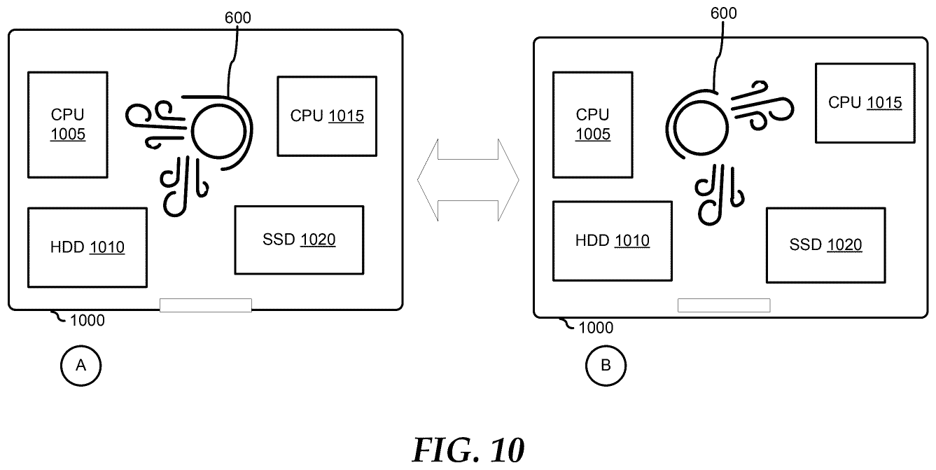

FIG. 10 shows an information handling system 1000 with air mover 600. Information handling system 1000, which is similar to information handling system 100 of FIG. 1, includes a CPU 1005, an HDD 1010, a CPU 1015, an SSD 1020, and air mover 600. CPU 1005 may be similar to processor 102 of FIG. 1 while CPU 1015 may be similar to processor 104 of FIG. 1. HDD 1010 may be similar to HDD 154 of FIG. 1 while SSD 1020 may be similar to SSD 164 of FIG. 1. In this example, SSD 1020 is disposed within information handling system 1000.

FIG. 10 is annotated with a series of letters A and B. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations.

At stage A, the temperature of CPU 1005 and/or HDD 1010 may have exceeded a temperature threshold and/or may be higher than the temperature of SSD 1020 and/or CPU 1015. Accordingly, the orientation of air mover 600 may be configured such that the airflow is directed toward CPU 1005 and/or HDD 1010. For example, outlet frame 625 may be rotated such that the airflow is directed to CPU 1005 and/or HDD 1010. This may lower the temperature of CPU 1005 and/or HDD 1010. In addition, the skin temperature of information handling system 1000 above CPU 1005 and/or HDD 1010 may also be reduced.

At stage B, the temperature of SSD 1020 and/or CPU 1015 may have exceeded a temperature threshold and/or may be higher than the temperature of CPU 1005 and/or HDD 1010. Accordingly, the orientation of air mover 600 may be configured such that the airflow is directed toward SSD 1020 and/or CPU 1015. For example, outlet frame 625 may be rotated such that the airflow is directed towards SSD 1020 and/or CPU 1015. This may lower the temperature of SSD 1020 and/or CPU 1015. In addition, the skin temperature of information handling system 1000 above SSD 1020 and/or CPU 1015 may also be reduced.

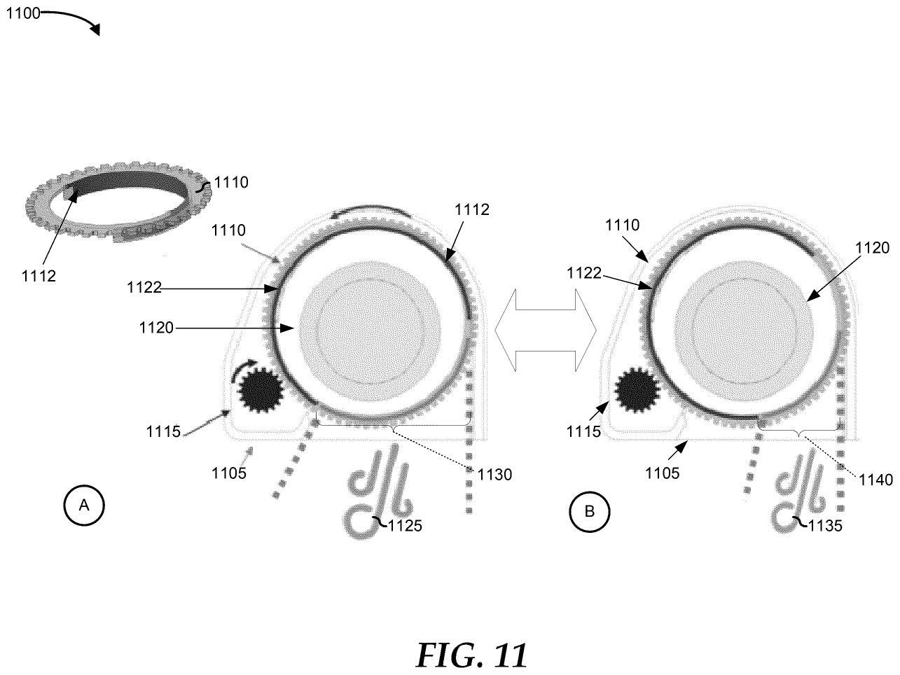

FIG. 11 shows an air mover 1100 with a rotatable air mover outlet for different user scenarios. Air mover 1100 includes an enclosure base 1105, an outlet frame 1110, a gear 1115, and a set of blades 1120. Outlet frame 1110, gear 1115, and set of blades 1120 may be disposed within enclosure base 1105 and a top cover. Enclosure base 1105 may be narrower than enclosure base 205 of FIG. 2. Outlet frame 1110 may be configured as a geared circular structure. In this embodiment, outlet frame 1110 may be configured similarly to a closed circle without a nozzle opening structure of outlet frame 215 of FIG. 2.

Outlet frame 1110 includes a circular outer gear that may be configured to engage with gear 1115 mounted on enclosure base 1105. Together, the circular outer gear of outlet frame 1110 and gear 1115 may cause outlet frame 1110 to rotate, which causes a change in the width of the airflow opening. This is because as the outlet frame rotates along a frame guide, an extended rim 1112 along a section of an edge of outlet frame 1110 rotates along an opening of the air mover enclosure, temporarily changing the width of the enclosure opening. For example, as extended rim 1112 rotates, it may block a section of the enclosure opening, such as an airflow opening 1315 of FIG. 13. Thus, the width of the opening may become narrower. For example, a change from airflow opening 1130 to airflow opening 1140, wherein airflow opening 1140 is narrower than airflow opening 1130. Because airflow opening 1140 is narrower than airflow opening 1130, an airflow 1135 at airflow opening 1140 may be faster than an airflow 1125 at airflow opening 1130. Correspondingly, a wider airflow opening may result in a slower airflow.

FIG. 11 is annotated with a series of letters A and B. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations.

As extended rim 1112 is rotated back or passes through the opening, a section of the edge of outlet frame 1110 without an extended rim may unblock the enclosure opening. Thus, the width of the enclosure opening may be wider. For example, a change from airflow opening 1140 in stage B to airflow opening 1130 in stage A. The change in the width of the enclosure opening may in turn cause a change in the speed of the airflow. A step motor may be utilized to rotate gear 1115, enabling precise control over the speed of the airflow.

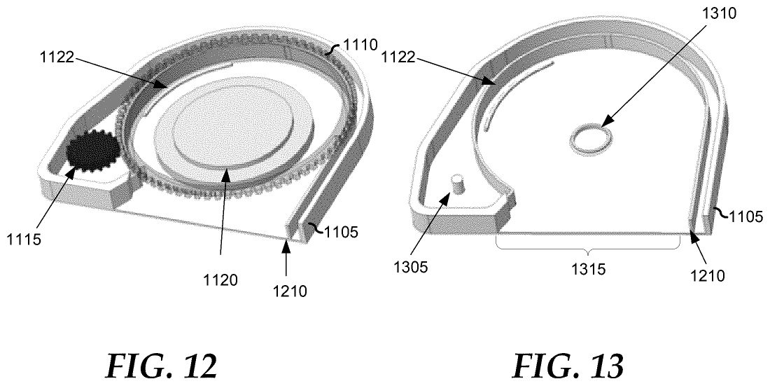

FIG. 12 shows a perspective view of air mover 1100. Air mover 1100 includes rib 1122, outlet frame 1110, gear 1115, and set of blades 1120. Outlet frame 1110 may be configured to rotate along guide 1210 and may be kept in place by rib 1122. The height of outlet frame 1110 may vary, such that a section of outlet frame 1110 with the extended rim is higher than a section of outlet frame 1110 without the extended rim.

FIG. 13 shows a perspective view of enclosure base 1105. Enclosure base 1105 includes enclosure base 1105, rib 1122, guide 1210, a peg 1305, and a ribbed opening 1310. Ribbed opening 1310 may support set of blades 1120 to keep it from sliding. Airflow opening 1315 may be located between two ends of guide 1210. Air flowing through airflow opening 1315 may be limited by the extended rim of outlet frame 1110 as it rotates through guide 1210. This is because the extended rim of the outlet frame may block portions of airflow opening 1315.

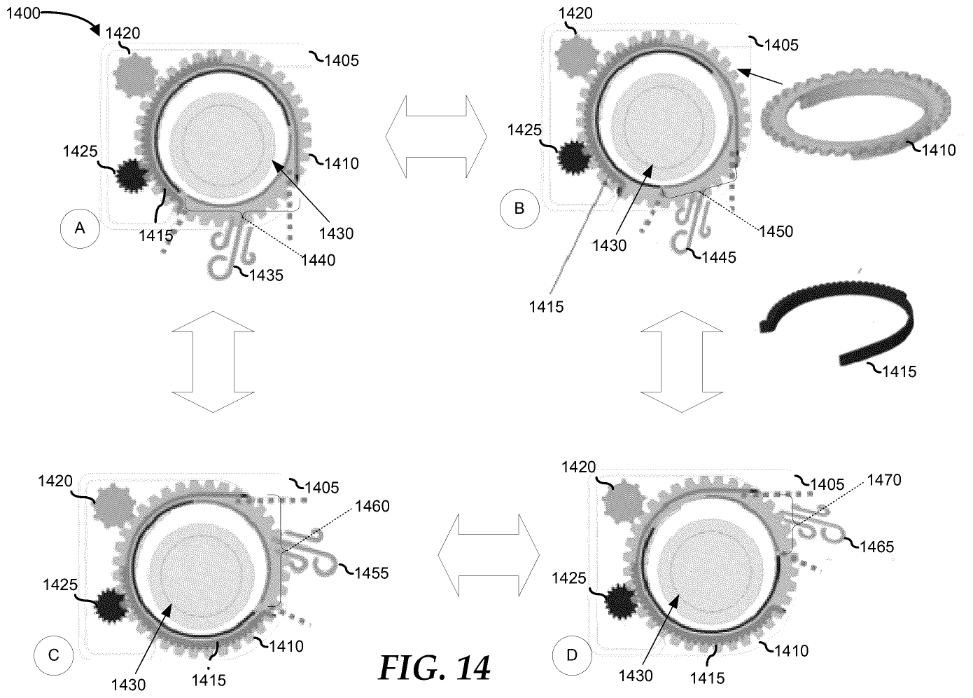

FIG. 14 shows an air mover 1400 with a rotatable air mover outlet for different user scenarios. Air mover 1400 includes an enclosure base 1405 with a top cover removed, an inner outlet frame 1410, an outer outlet frame 1415, an inner frame gear 1420, an outer frame gear 1425, and a set of blades 1430. Inner outlet frame 1410, outer outlet frame 1415, inner frame gear 1420, outer frame gear 1425, and set of blades 1430 may be disposed between enclosure base 1405 and the top cover. Inner outlet frame 1410 may be configured as a geared circular structure that is similar to a closed circle without a nozzle opening. In comparison, outer outlet frame 1415 may be configured as a geared circular structure with a nozzle opening. In addition to controlling airflow direction, air mover 1400 may be configured to also control the speed of the airflow. For example, outer outlet frame 1415 may be configured to change the direction of the airflow while inner outlet frame 1410 may be configured to change the velocity of the airflow. Accordingly, air mover 1400 may provide an optimized performance according to a specific user scenario.

Inner outlet frame 1410 may include a circular outer gear that may be configured to engage with inner frame gear 1420 which is mounted on enclosure base 1405. Together the circular outer gear of inner outlet frame 1410 and inner frame gear 1420 may cause inner outlet frame 1410 to rotate which causes a change in the speed of airflow due to a change in the width of an airflow opening, such as an airflow opening 1440. This in turn may cause a change in the speed of the airflow, wherein the narrower the airflow opening, the faster the speed. A step motor may be run to rotate inner frame gear 1420, enabling control over the speed of the airflow.

Outer outlet frame 1415 may include a circular outer gear that may be configured to engage with outer frame gear 1425 mounted on enclosure base 1405. Together, the circular outer gear of outer outlet frame 1415 and outer frame gear 1425 may cause outer outlet frame 1415 to rotate changing its orientation. This in turn may cause a change in the direction of the airflow. A step motor may be run to rotate outer frame gear 1425, enabling control over the direction of the airflow.

FIG. 14 is annotated with a series of letters A, B, C, and D. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations.

At stage A, air mover 1400 may be oriented such that air flows in an airflow direction 1435 through airflow opening 1440. In addition, the extended rim of inner outlet frame 1410 may be positioned, such that it does not block the opening of enclosure base 1405 which allows for maximum amount of airflow. Accordingly, airflow opening 1440 may be the widest airflow opening. As such, airflow speed may be slowest at this orientation.

At stage B, air mover 1400 may be oriented, such that air flows in an airflow direction 1445 through an airflow opening 1450. In this example, airflow direction 1435 may be similar to airflow direction 1445. However, because airflow opening 1450 may be narrower than airflow opening 1440, the flow of air at airflow opening 1440 may be faster than the airflow through airflow opening 1440. Airflow direction 1445 may be similar to airflow direction 1435.

At stage C, air mover 1400 may be oriented such that air flows in an airflow direction 1455 through airflow opening 1460. In this stage, the width of airflow opening 1460 may be similar to airflow opening 1440. Accordingly, the speed or amount of air that flows through airflow opening 1440 may be similar. However, airflow direction 1435 may be different from airflow direction 1455.

At stage D, air mover 1400 is oriented such that air flows in an airflow direction 1465 through airflow opening 1470. In this example, airflow direction 1455 may be similar to airflow direction 1465. However, because airflow opening 1470 may be narrower than airflow opening 1460, the airflow at airflow opening 1470 may be faster than the airflow through airflow opening 1460. Air mover 1400 may change its orientation from one stage A to another stage, such as stage B, C, or D. Similarly, air mover 1400 may change its orientation from stage B to another stage, such as stage A, C, or D. Accordingly, air mover 1400 may change its orientation from stage C to another stage, such as stage A, B, and D. Further, air mover 1400 may change its orientation from stage D to another stage, such as stage A, B, or C.

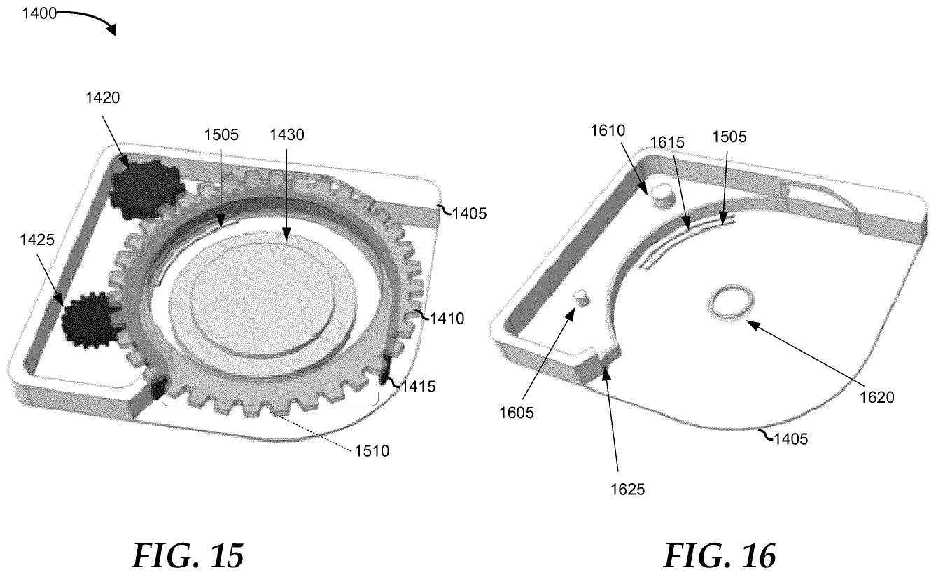

FIG. 15 shows a perspective view of air mover 1400. Air mover 1400 includes enclosure base 1405 with a top cover removed, inner outlet frame 1410, outer outlet frame 1415, inner frame gear 1420, outer frame gear 1425, set of blades 1430, and an inner frame rib 1505. The airflow may flow through airflow opening 1510 which is shaped by the ends of outer outlet frame 1415.

FIG. 16 shows a perspective view of enclosure base 1405. Enclosure base 1405 includes inner frame rib 1505, an outer frame rib 1615, an outer gear peg 1605, an inner gear peg 1610, and a ribbed opening 1620. Outer outlet frame 1415 may be configured to be kept in place by outer frame rib 1615. Inner outlet frame 1410 may be configured to rotate along guide 1625 and be kept in place by inner frame rib 1505. Set of blades 1430 may be kept in place by ribbed opening 1620. In the examples above, an enclosure of air mover 1400 may include a top cover that may be physically coupled with enclosure base 1405. However, for ease in showing the components, air mover 1400 is presented with the top cover removed.

In one embodiment, the enclosure base, set of blades, outlet frames, ribs, gears, and/or other components or portions thereof of the air movers depicted above may be manufactured using one or a combination of suitable materials, such as a metal like steel, aluminum, or the like. Other suitable material includes polymers, such as polyamides, polycarbonates, polyester, polyethylene, polypropylene, polystyrene, polyurethanes, polyvinyl chloride, etc.

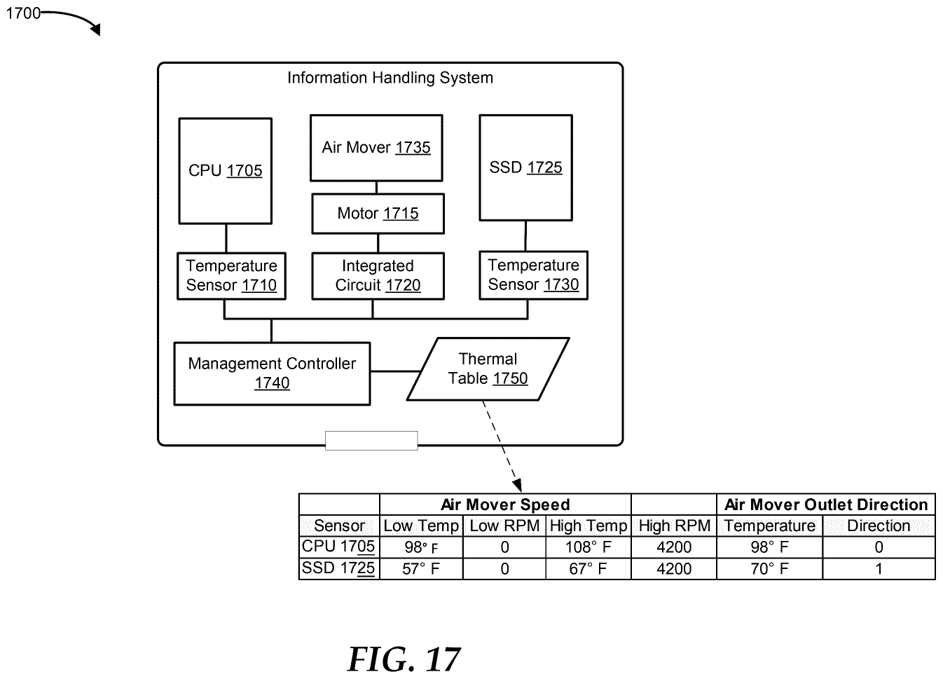

FIG. 17 shows an information handling system 1700 with an air mover that is configured with a rotatable fan outlet for different user scenarios. Information handling system 1700, which is similar to information handling system 100 of FIG. 1 includes a CPU 1705, a temperature sensor 1710, a motor 1715, an integrated circuit 1720, an SSD 1725, a temperature sensor 1730, an air mover 1735, a management controller 1740, and a thermal table 1750.

Air mover 1735 may be communicatively coupled to management controller 1740 and motor 1715. Motor 1715 may be communicatively coupled to air mover 1735 and integrated circuit 1720. Management controller 1740 may be communicatively coupled to temperature sensor 1710, temperature sensor 1730, and integrated circuit 1720. Management controller 1740 may also have access to thermal table 1750 which may be stored in a non-volatile storage device, such as a memory associated with management controller 1740. Management controller 1740 may include an air mover control system which in turn may control and/or monitor air mover 1735.

Air mover 1735 may include a mechanical or electro-mechanical system, apparatus, or device operable to move air and/or other gases. In some embodiments, air mover 1735 may comprise a fan, such as a centrifugal fan that employs rotating impellers to move air received at its intake. In operation, the air mover may cool information handling system resources by drawing cool air into an enclosure housing the information handling system from outside the chassis, expel warm air from inside the enclosure to the outside of such enclosure, and move air across one or more resources internal to the enclosure to cool the one or more resources. In one embodiment, the information handling system may include more than one air mover.

Air mover 1735 may also include an outlet frame which can change the direction of the airflow. In addition, air mover 1735 may also include another frame that can change the speed of the airflow. For example, the other frame may be used to accelerate or decelerate the airflow by changing the width of an opening for the airflow. Thus, the direction and speed of the airflow may be controlled.

Management controller 1740, which is similar to BMC 190 of FIG. 1, may be configured to receive signals from one or more thermal sensors, such as temperature sensors 1710 and 1730. Thus, temperature sensors 1710 and 1730 may be configured to communicate with management controller 1740 via signals. Temperature sensors 1710 and 1730 may be a system, device, or apparatus configured to communicate a signal to management controller 1740 indicative of a temperature associated with one or more resources of information handling system 1700, such as CPU 1705 and SSD 1725, respectively.

Based on the signals and/or thermal parameters, management controller 1740 may determine the speed of air mover 1735 in revolutions per minute and its airflow direction to maintain an appropriate level of cooling, increase cooling, or decrease cooling as appropriate to the information handling system resource. In one example, management controller 1740 may determine the revolutions per minute and the airflow direction by utilizing thermal table 1750. Management controller 1740 may communicate the speed and/or the airflow direction to motor 1715 via a signal transmitted to integrated circuit 1720. Integrated circuit 1720 in turn may control the rotation of motor 1715 by controlling an output of one or more pins connected to motor 1715, wherein the output of one or more pins may be triggered by a temperature value or thermal signal from one or more temperature sensors. The thermal signal may indicate the current temperature of an associated resource.

The rotation of motor 1715 may in turn control the airflow direction. In another embodiment, motor 1715 may control the speed of airflow by controlling the width of the airflow opening. Although information handling system 1700 is shown with one motor, information handling system 1700 may include two motors, wherein a first motor may control the airflow direction while a second motor may control the speed of airflow. Each motor may be associated with an integrated circuit. However, the integrated circuit may be configured to control both motors.

Thermal table 1750 may include a map, list, array, table, or other suitable data structure with one or more entries, each entry setting includes thermal parameters regarding an information handling resource. In particular, thermal table 1750 may set forth thermal parameters, such as air mover outlet direction and air mover speed, for known or supported information handling resources that may be used in the information handling system. Thermal table 1750 may be constructed and stored within a read-only memory of management controller 1740 prior to the runtime of information handling system 1700, such as during factory provisioning. Thermal table 1750 may be updated in connection with periodic firmware updates to the management controller 1740.

Those of ordinary skill in the art will appreciate the configuration, hardware, and/or software components of information handling system 1700 depicted in FIG. 17 may vary. For example, the illustrative components within information handling system 1700 are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for continuity of the description.

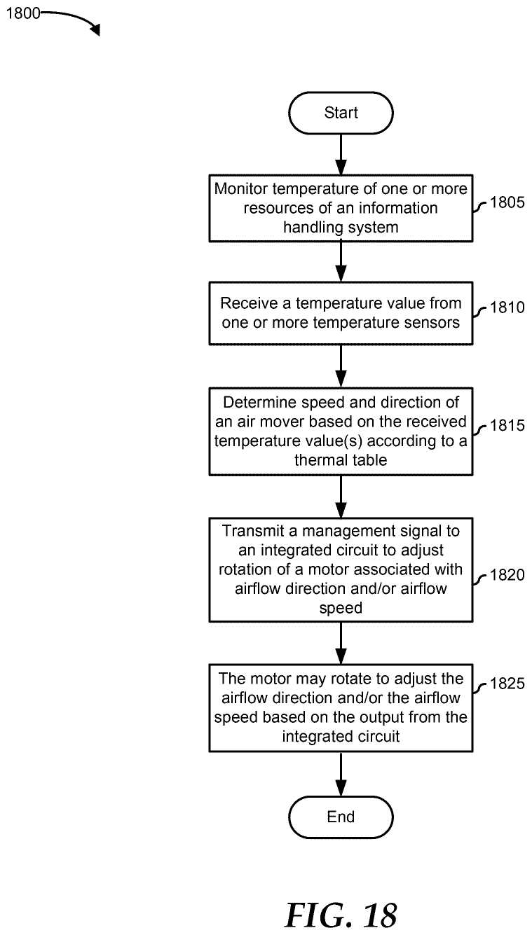

FIG. 18 shows a flowchart of a method 1800 for monitoring and/or controlling an air mover that is configured with a rotatable fan outlet for different user scenarios. Method 1800 may be performed by one or more components of information handling system 1700 of FIG. 17. However, while embodiments of the present disclosure are described in terms of information handling system 1700 of FIG. 17, it should be recognized that other systems may be utilized to perform the described method. One of skill in the art will appreciate that this flowchart explains a typical example, which can be extended to advanced applications or services in practice.

Method 1800 typically starts at block 1805 where the embedded controller may monitor the temperature of one or more resources of an information handling system, such as a CPU, a storage device like an SSD, an HDD, an ODD, or the like. At this point, an air mover may be running with a default airflow speed and default airflow direction. The default airflow speed and/or the default airflow direction may be set at a factory during the manufacture of the information handling system based on its configuration. The airflow speed may be based on the rotational speed of the air mover and the width of an airflow opening of the air mover. At this point, the air mover may also be configured to have a default width for the airflow opening.

The method may proceed to block 1810 where the embedded controller may receive a temperature value from one or more temperature sensors. Each one of the temperature sensors may be associated with and monitoring one or more resources. For example, temperature sensor 1710 may monitor the temperature of CPU 1705 and send temperature values of CPU 1705 to management controller 1740. Temperature sensor 1730 may monitor the temperature of SSD 1725 and send temperature values of SSD 1725 to management controller 1740.

The method may proceed to block 1815 where the embedded controller may determine the rotational speed of the air mover and airflow direction based on the received temperature values. The embedded controller may also determine the airflow speed. The embedded controller may use various means to determine the rotational speed, airflow direction, and airflow speed. The embedded controller may also determine the width of the airflow opening of the air mover. Adjusting the width of the airflow opening may change the speed of the airflow without changing the rotational speed of the air mover. For example, to increase the airflow speed, the width of the airflow opening may be decreased. Accordingly, to decrease the airflow speed, the width of the airflow opening may be increased.

In one example, the determination of the rotational speed of the air mover, the airflow direction, and/or the airflow speed may be on the received temperature values according to a thermal table. In one embodiment, if the temperature of a resource is above a certain threshold and/or is greater than the temperature of another resource, then the management controller may determine whether to use an air mover to lower the temperature of the resource. For example, based on thermal table 1750 if the temperature of the CPU 1705 is equal to or greater than 98° F., then an air mover direction flag may be set to zero. This may direct a gear of the air mover to rotate in one direction such that the airflow of the air mover is towards CPU 1705. The management controller may also set the rotational speed of the air mover according to thermal table 1750. In addition, the management controller may set the rotation of another gear of the air mover to adjust the width of the airflow opening of the air mover. This may adjust the speed of the air that flows from the air mover.

In this example, the management controller may determine that the rotational speed of the air mover should be 4200 revolutions per minute (RPM). In another example, based on thermal table 1750 if the temperature of SSD 1725 is equal to or greater than 70° F., then the air mover direction flag may be set to one. This may direct a gear of the air mover to rotate in another direction such that the airflow of the air mover is towards SSD 1725. The rotational speed of the air mover may also be determined to be 4200 RPM. In addition, the management controller may set the rotation of another gear of the air mover to change the width of the airflow opening of the air mover.

The method proceeds to block 1820 where the management controller may transmit a pulse width modulation signal to the air mover to adjust the air mover's rotational speed. The management controller may also transmit a management signal to update an output of a set of one or more pins of an integrated circuit that are associated with a motor that adjusts the direction of the airflow opening of the air mover by rotating a gear. The gear in turn may rotate an outlet frame associated with changing the direction of the airflow if applicable. In addition, the management controller may also update the output of another set of one or more pins of another integrated circuit that are associated with another motor that adjusts the width of the airflow opening of the air mover by rotating another gear. The other gear may rotate an outlet frame associated with changing the velocity of air that flows through the airflow opening.

In another embodiment, one integrated circuit may control the speed and direction of rotation of two motors, accordingly, the management controller may adjust the output of one or more pins associated with the rotation of the two motors. Each of the two motors may be configured to rotate a gear, wherein one gear may be configured to adjust the direction of the airflow and another gear to adjust the speed of the air that flows through the airflow opening. The method proceeds to block 1825 where a motor may adjust the airflow direction and/or another motor may adjust the airflow speed of the air mover. The airflow direction may be adjusted independently of the adjustment of the airflow speed.

Although FIG. 18 shows example blocks of method 1800 in some implementations, method 1800 may include additional blocks, fewer blocks, different blocks, or differently arranged blocks than those depicted in FIG. 18. Those skilled in the art will understand that the principles presented herein may be implemented in any suitably arranged processing system. Additionally, or alternatively, two or more of the blocks of method 1800 may be performed in parallel. For example, blocks 1805 and 1810 of method 1800 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A method comprising:
monitoring, by a management controller, a temperature of a resource of an information handling system via a temperature sensor;
receiving a value of the temperature of the resource of the information handling system from the temperature sensor;
determining a direction of an airflow of an air mover based on the value of the temperature; and
rotating an outlet frame of the air mover according to the direction of the airflow.

2. The method of claim 1, wherein the rotating of the outlet frame is performed by a gear coupled to the outlet frame.

3. The method of claim 1, wherein the outlet frame is configured with a nozzle structure.

4. The method of claim 1, further comprising transmitting a management signal to an integrated circuit associated with a motor utilized to rotate a gear coupled to the outlet frame.

5. The method of claim 4, further comprising providing, by the integrated circuit, an output to a pin connected to the motor based on the management signal.

6. The method of claim 1, further comprising rotating another outlet frame to change speed of the airflow of the air mover.

7. The method of claim 1, wherein the determining of the direction of the airflow is according to a thermal table.

8. The method of claim 1, wherein the direction of the airflow is towards the resource of the information handling system.

9. An information handling system, comprising:
an air mover; and
a management controller configured to determine an airflow direction of the air mover;
wherein the air mover includes:
an enclosure base;
a gear disposed within the enclosure base, the gear configured to rotate an outlet frame; and
the outlet frame configured to rotate within the enclosure base, the outlet frame including a nozzle structure that is configured to guide the airflow direction according to a determination of the management controller.

10. The information handling system of claim 9, wherein the air mover further includes another outlet frame configured to adjust airflow speed.

11. The information handling system of claim 9, further comprising a motor configured to rotate the gear.

12. The information handling system of claim 9, wherein the air mover further includes another gear to rotate another outlet frame to adjust airflow speed.

13. The information handling system of claim 12, wherein the other outlet frame includes an extended rim.

14. The information handling system of claim 12, further comprising a motor configured to rotate the other gear.

15. An air mover comprising:
an enclosure base; and
a gear disposed within the enclosure base, wherein the gear is configured to rotate an outlet frame; and
the outlet frame configured to rotate within the enclosure base, the outlet frame including a nozzle structure that is configured to guide an airflow direction according to a determination of a management controller.

16. The air mover of claim 15, further comprising a motor configured to rotate the gear.

17. The air mover of claim 15, further comprising another outlet frame configured to adjust airflow speed.

18. The air mover of claim 17, wherein the other outlet frame includes an extended rim.

19. The air mover of claim 15, wherein the air mover further includes another gear to rotate another outlet frame to adjust airflow speed.

20. The air mover of claim 19, further comprising a motor configured to rotate the other gear.
